(19) United States
(12) Patent Application Publication
(10) Pub. No.: US 2026/0136599 A1
(43) Pub. Date: May 14, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Hong-Chih CHEN, Changhua County (TW); Ta-Chun LIN, Hsinchu (TW); Ruoh-Ning TZENG, New Taipei City (TW); Jhon-Jhy LIAW, Zhudong Township (TW)

(21) Appl. No.: 18/944,719

(22) Filed: Nov. 12, 2024

(51) Int. Cl. H01L 29/423; H01L 21/8238; H01L 27/092; H01L 29/06; H01L 29/417; H01L 29/66; H01L 29/775; H01L 29/786

(52) U.S. Cl. CPC H10D 30/6735; H10D 30/014; H10D 30/43; H10D 30/6729; H10D 30/6757; H10D 62/121; H10D 64/017; H10D 64/018; H10D 84/0188; H10D 84/038; H10D 84/85; H10D 84/856; H10D 30/6736

(57) ABSTRACT

Semiconductor structures and methods for manufacturing the same are provided. The semiconductor structure includes a plurality of first nanostructures formed over a substrate along a first direction, and a gate structure formed over the first nanostructures along a second direction. The semiconductor structure includes an S/D structure formed adjacent to the gate structure, and a dielectric layer formed on the S/D structure. The semiconductor structure includes a plurality of inner spacer layers between the gate structure and the S/D structure. A thickness of a topmost inner spacer layer is greater than a thickness of a bottommost inner spacer layer, and a top surface of the topmost inner spacer layer is higher than a bottom surface of the dielectric layer.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3K-1 illustrate cross-sectional representations of various stages of manufacturing the semiconductor structure shown along line A-A′ in FIG. 1E and in FIG. 2, in accordance with some embodiments.

FIGS. 3A-2 to 3K-2 illustrate cross-sectional representations of various stages of manufacturing the semiconductor structure shown along line B-B′ in FIG. 1E and in FIG. 2, in accordance with some embodiments.

FIGS. 3A-3 to 3K-3 illustrate cross-sectional representations of various stages of manufacturing the semiconductor structure shown along line C-C′ in FIG. 1E and in FIG. 2, in accordance with some embodiments.

FIG. 3K-4 illustrate cross-sectional representations of various stages of manufacturing the semiconductor structure shown along line D-D′ in FIG. 1E and in FIG. 2, in accordance with some embodiments.

FIG. 4 illustrate a cross-sectional representation of manufacturing a semiconductor structure after FIG. 3K-3, in accordance with some embodiments.

FIG. 5 illustrate a cross-sectional representation of a semiconductor structure after FIG. 3K-3, in accordance with some embodiments.

FIGS. 6A to 6B illustrate cross-sectional representations of various stages of manufacturing a semiconductor structure, in accordance with some embodiments.

FIG. 7 illustrates a cross-sectional representation of a semiconductor structure, in accordance with some embodiments.

FIG. 8 shows a perspective view of a semiconductor structure, in accordance with some embodiments.

FIG. 9A-1 shows the cross-sectional representation of various stages of manufacturing the semiconductor structure shown along line A-A′ in FIG. 8, in accordance with some embodiments.

FIG. 9A-2 shows the cross-sectional representation of various stages of manufacturing the semiconductor structure shown along line B-B′ in FIG. 8, in accordance with some embodiments.

FIG. 10A-1 shows a cross-sectional representation of various stages of manufacturing the semiconductor structure shown along line A-A′ in FIG. 8, in accordance with some embodiments.

FIG. 10A-2 shows a cross-sectional representation of various stages of manufacturing the semiconductor structure shown along line B-B′ in FIG. 8, in accordance with some embodiments.

FIG. 10A-3 shows a cross-sectional representation of various stages of manufacturing the semiconductor structure shown along line C-C′ in FIG. 8, in accordance with some embodiments.

FIGS. 11A to 11G illustrate cross-sectional representations of various stages of manufacturing a semiconductor structure, in accordance with some embodiments.

FIGS. 12A to 12C illustrate cross-sectional representations of various stages of manufacturing a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structure includes a fin structure formed on a substrate. The fin structure includes first semiconductor material layers and the second semiconductor material layers alternatively stacked. A dummy gate structure is formed on the sidewall surfaces of the fin structure. A pair of gate spacer layers are formed on the sidewall surfaces of the gate structure. Next, an S/D structure is formed adjacent to the gate structure, and a plurality of inner spacer layers formed between the gate structure and the S/D structure. Next, the dummy gate structure is replaced with a gate structure. Afterwards, the top portion of the gate structure and the gate spacer layers are removed to expose the inner spacer layer. As a result, the profile of the gate structure is improved. In other words, the profile of the topmost gate structure is substantially the same with the profile of the bottommost gate structure. The unwanted footing issue of the gate structure is prevented. When the uniformity of the profiles of the gate structure are improved, the variation of threshold voltage (Vt) of the semiconductor structure and the variation of the DIBL (Drain Induced Barrier Lowering) are improved. Therefore, the performance of the semiconductor structure is improved. The source/drain(S/D) structure or region(s) may refer to a source or a drain, individually or collectively dependent upon the context.

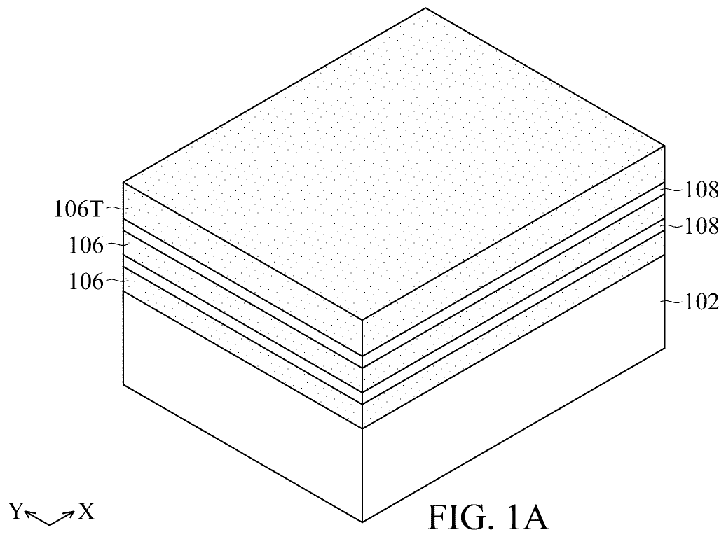

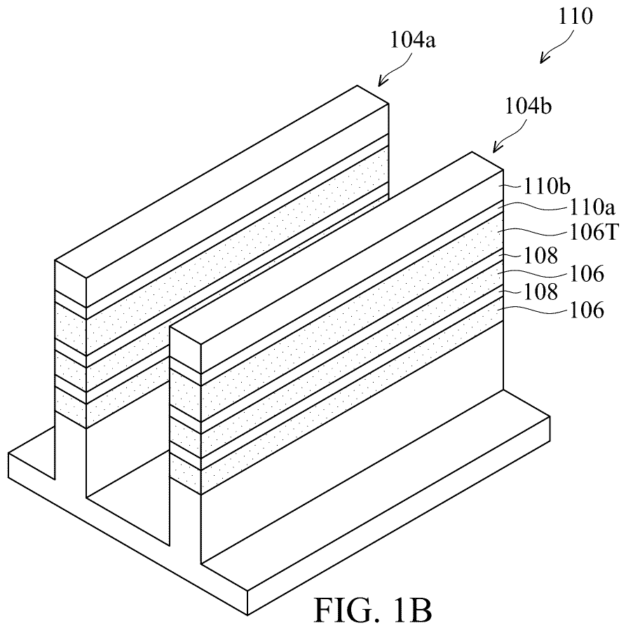

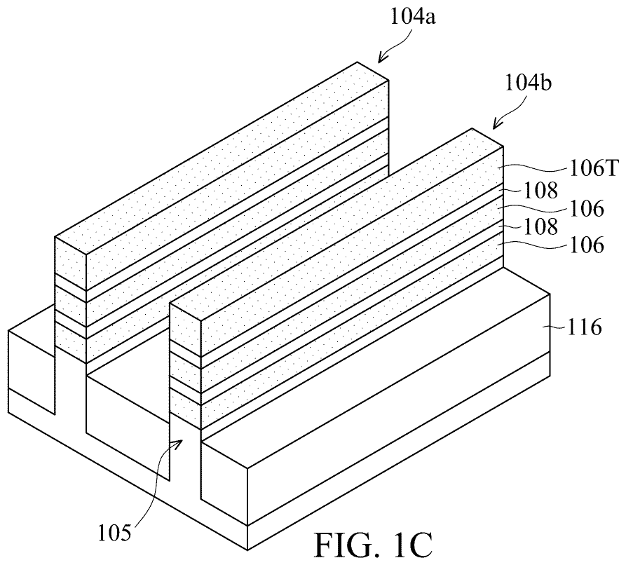

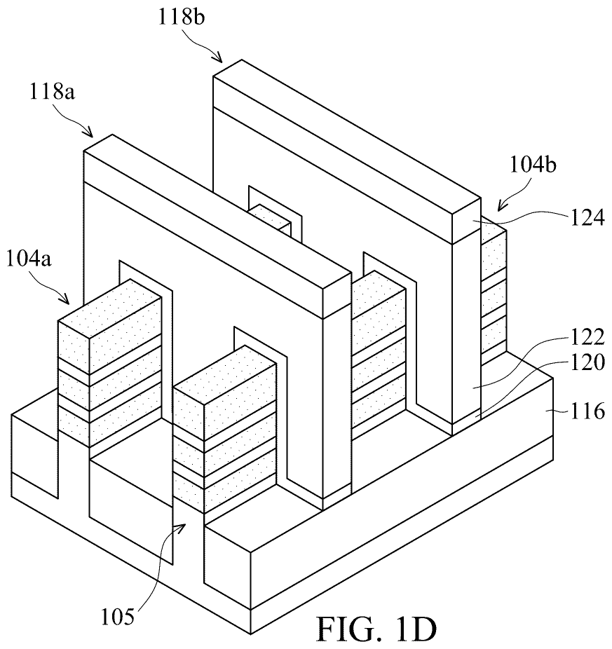

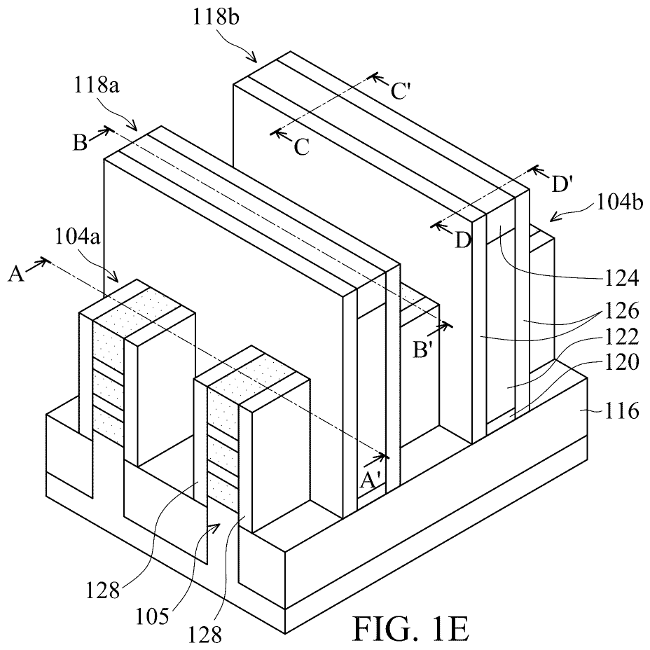

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are alternatively stacked and formed over a substrate 102. The topmost first semiconductor material layer 106T is formed on the top. The thickness of the topmost first semiconductor material layer 106T is greater than the thickness of the other first semiconductor material layer 106. In some embodiments, the ratio of the topmost first semiconductor material layer 106T to the thickness of the other one of first semiconductor material layers 106 is in a range from about 1 to about 1.32. In some embodiments, the topmost first semiconductor material layer 106T has the thickness in a range from about 4.2 nm to about 6.2 nm. In some embodiments, the other one of first semiconductor material layers 106 has a thickness in a range from about 4.2 nm to about 4.7 nm.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that the number of the first semiconductor material layers 106 is greater than the number of the second semiconductor material layers 108, the number of the first semiconductor material layers 106 may include four or five. The number of the first semiconductor material layers 106 can be adjusted according to actual application.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 110a and a nitride layer 110b formed over the pad oxide layer 110a. The pad oxide layer 110a may be made of silicon oxide, which is formed by thermal oxidation or chemical vapor deposition (CVD), and the nitride layer 110b may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b are protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, first dummy gate structures 118a and second dummy gate structures 118b are formed across the first fin structure 104a and the second fin structure 104b and extend over the isolation structure 116, in accordance with some embodiments. The first dummy gate structures 118a and the second dummy gate structures 118b may be used to define the source/drain (S/D) regions and the channel regions of the resulting semiconductor structure 100a.

In some embodiments, each of the first dummy gate structures 118a and each of the second dummy gate structures 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, as shown in FIG. 1E, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the first dummy gate structure 118a, the second dummy gate structures 118b and support the first dummy gate structure 118a, the second dummy gate structures 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), applicable low-k dielectric materials, and/or a combination thereof. In some embodiments, the gate spacer layers 126 and the fin spacer layers 128 are multiple layers.

The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

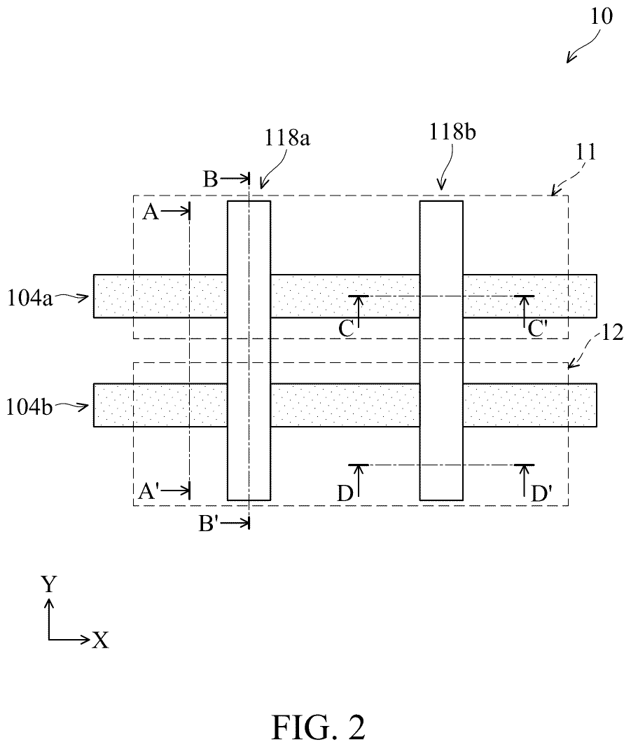

FIG. 2 shows a top-view representation of the semiconductor structure 100a, in accordance with some embodiments. As shown in FIG. 2, the substrate 102 includes a first region 10, and the first region 10 includes a first sub-region 11 and a second sub-region 12. The first fin structure 104a is formed in the first sub-region 11 along a first direction (e.g. X-axis), and the second fin structure 104b is formed in the second sub-region 12 along the first direction (e.g. X-axis). A first dummy gate structure 118a and a second dummy gate structure 118b are formed along a second direction (e.g. Y-axis). The first dummy gate structure 118a and the second dummy gate structure 118b are formed across the first fin structure 104a and the second fin structure 104b.

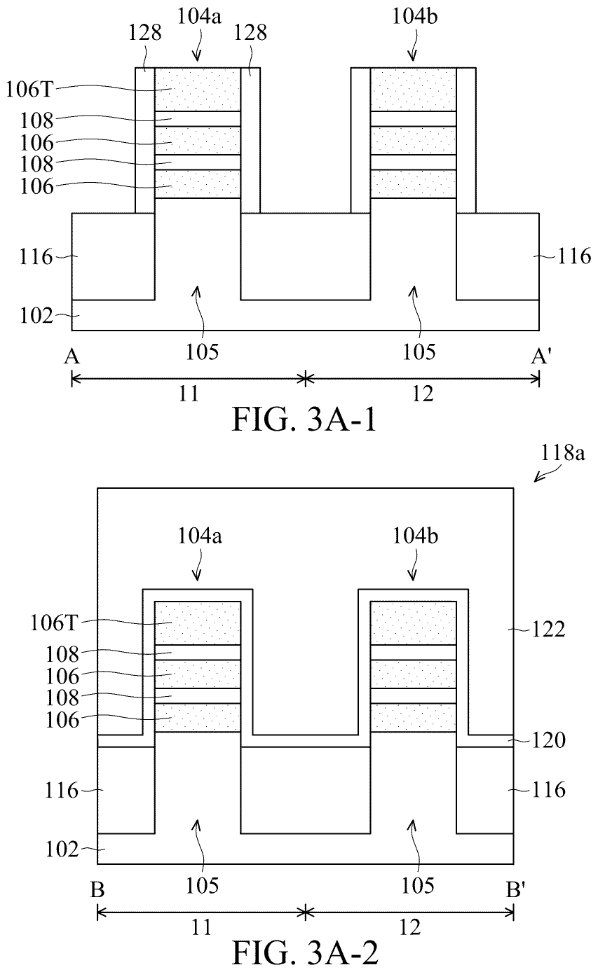

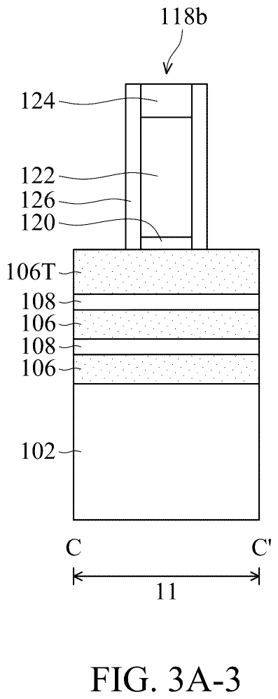

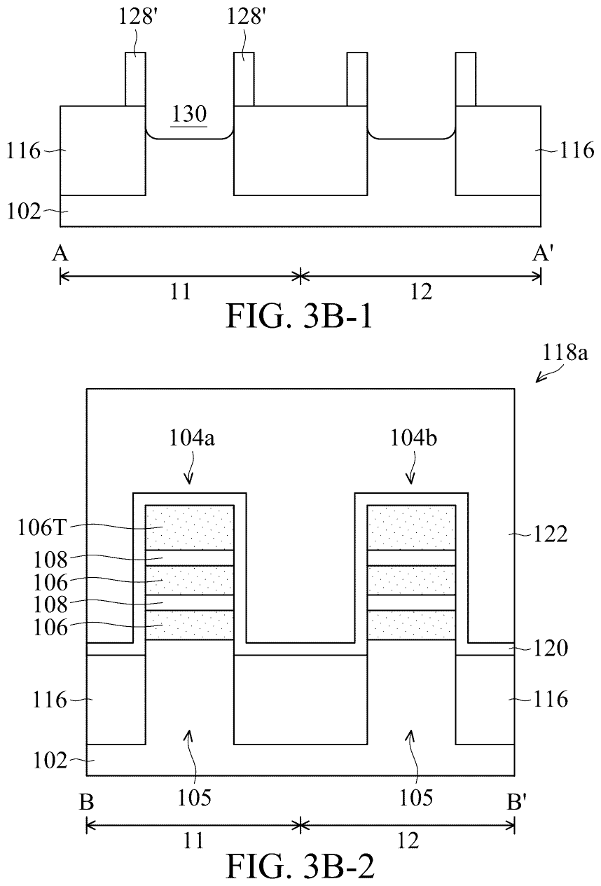

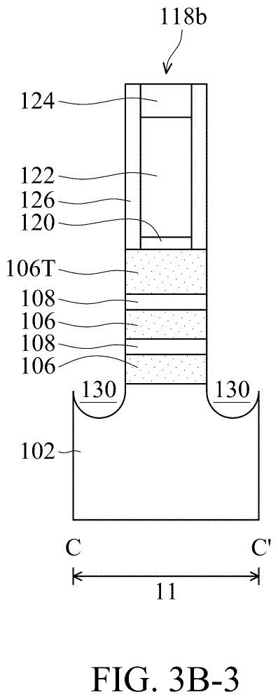

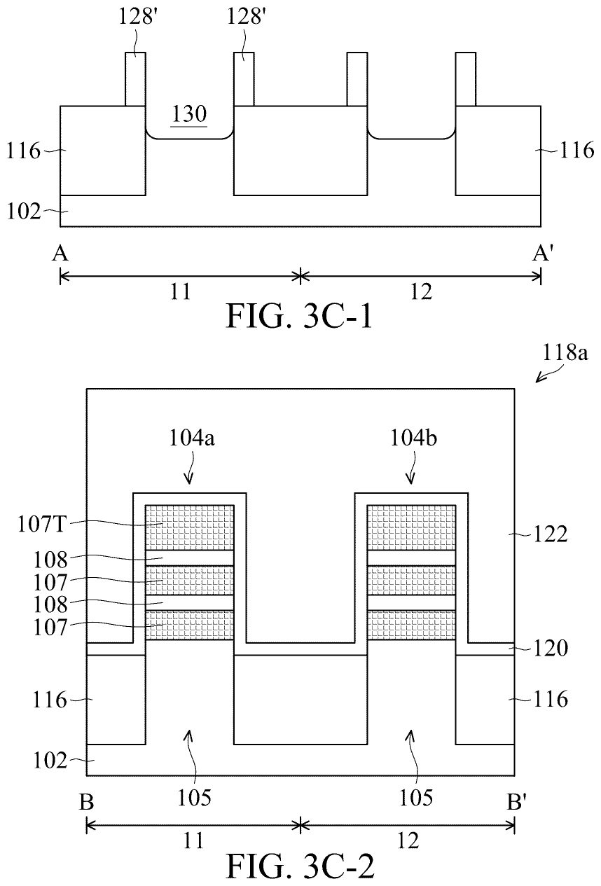

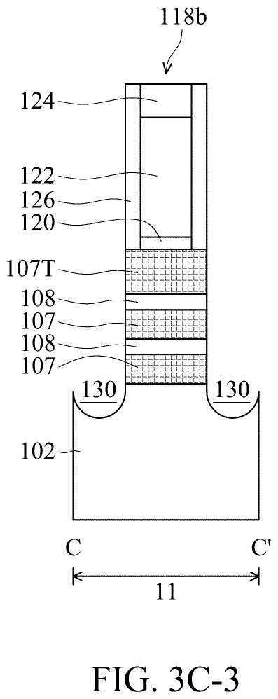

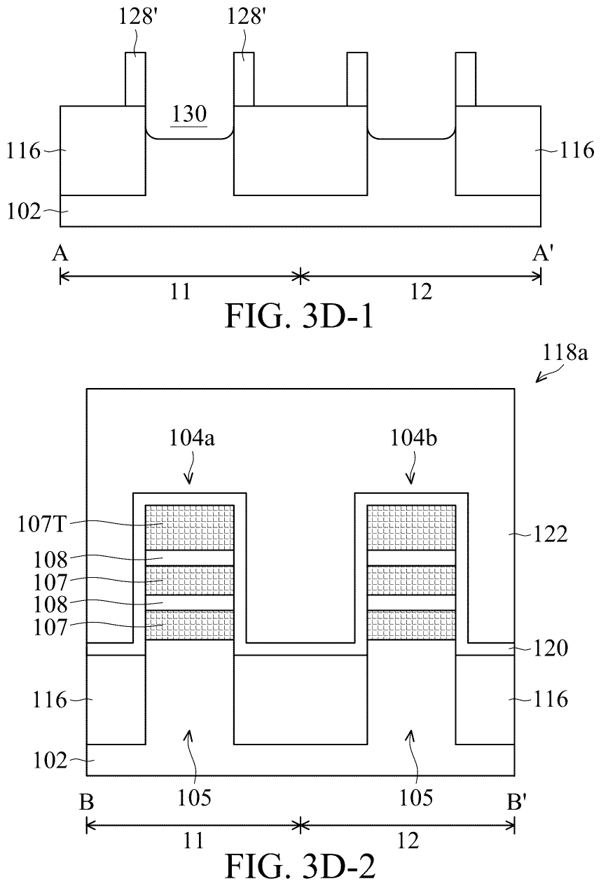

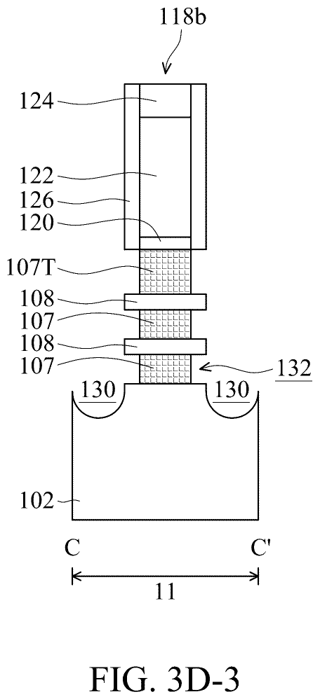

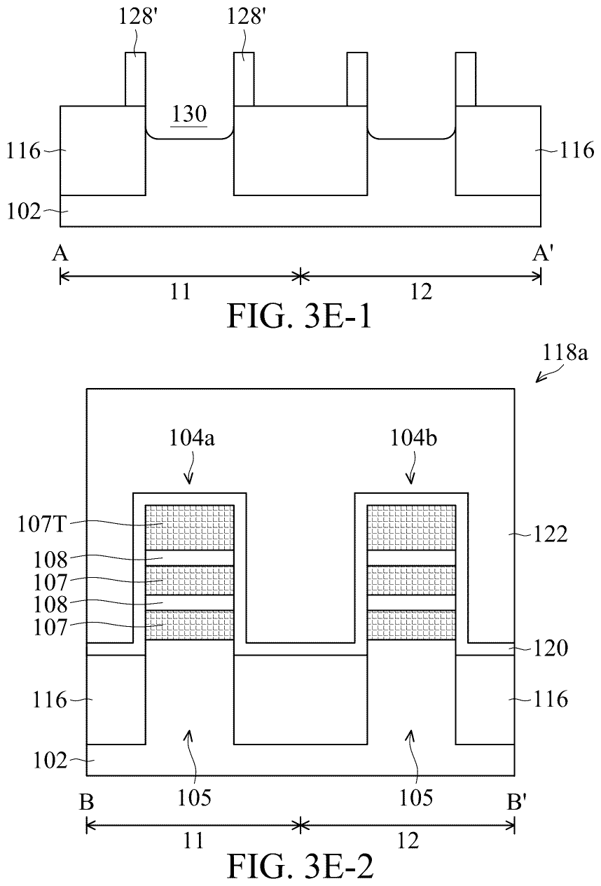

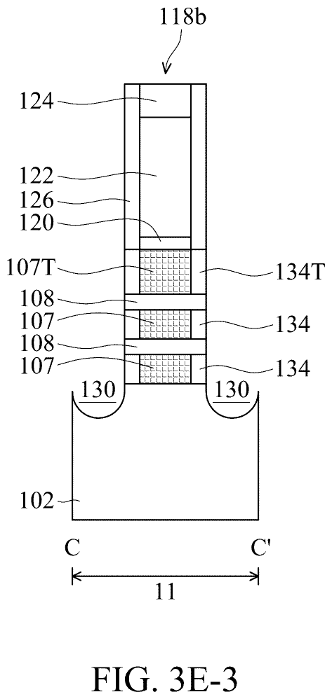

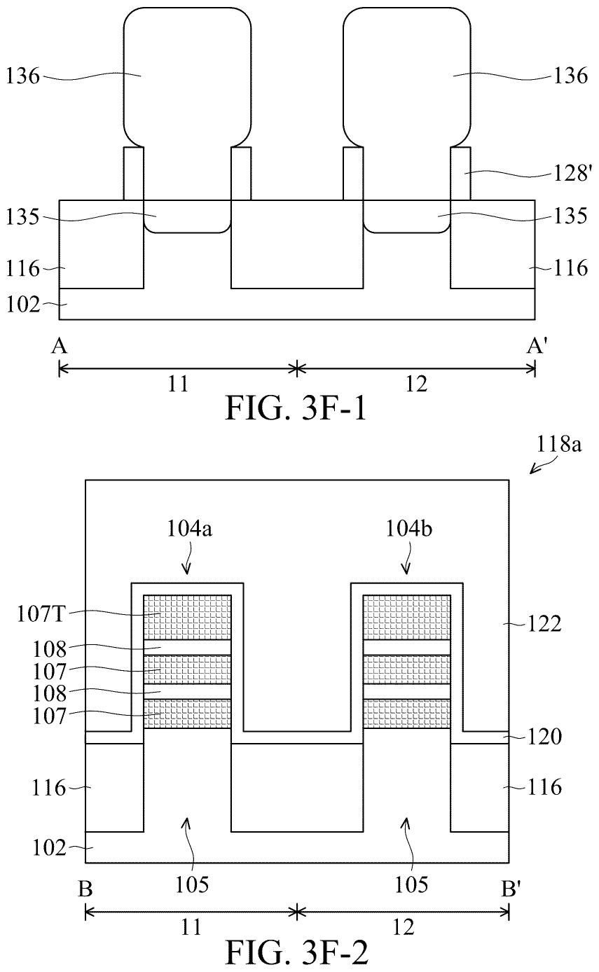

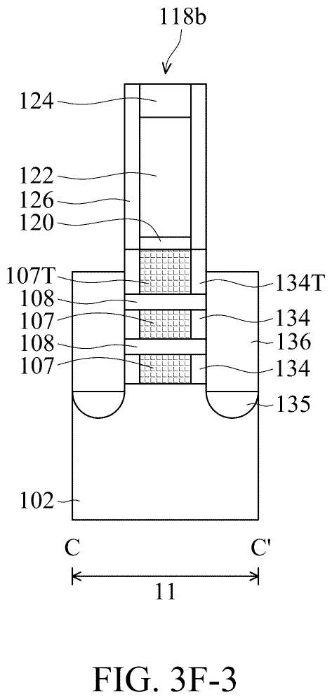

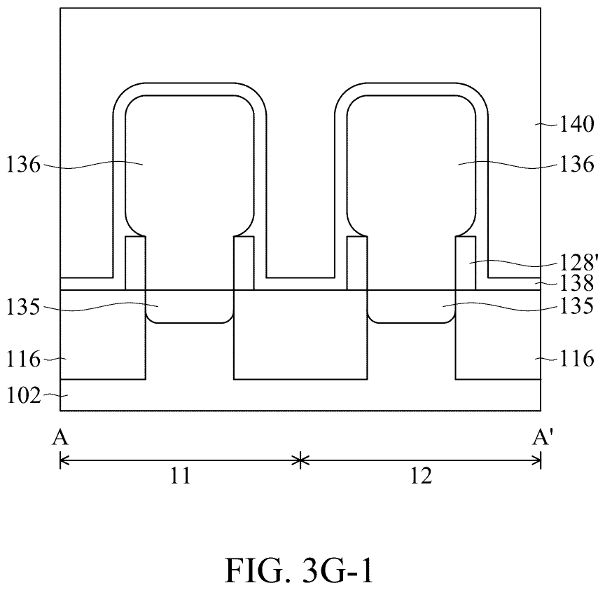

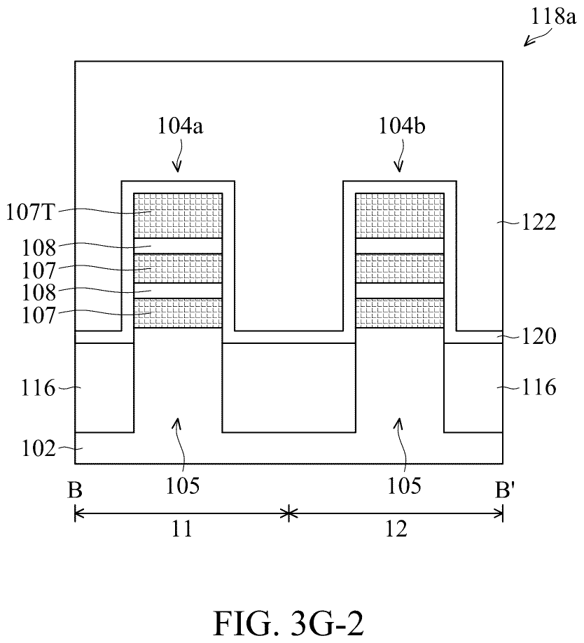

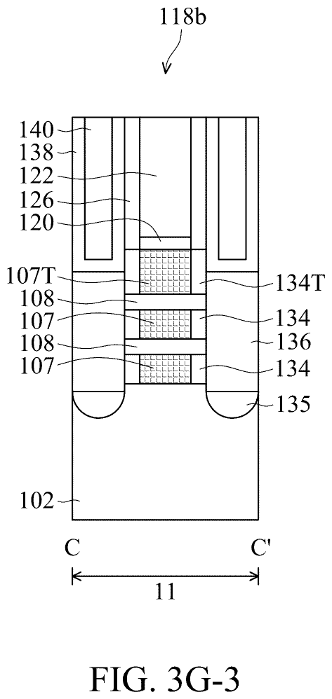

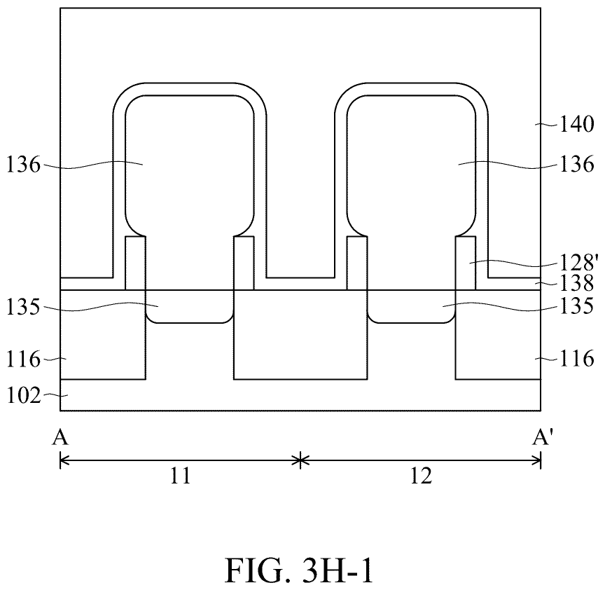

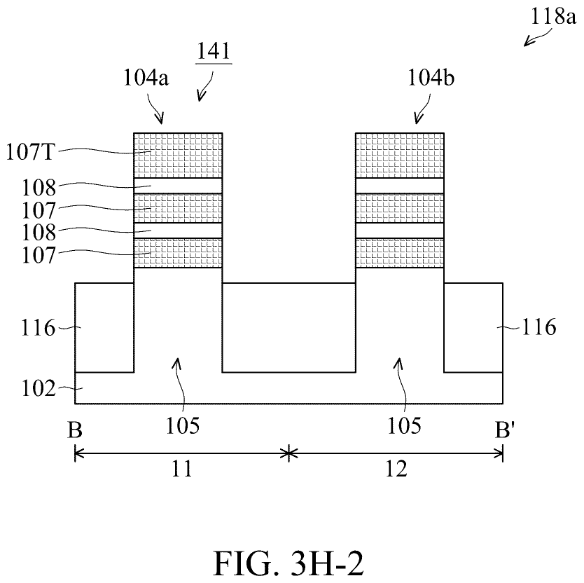

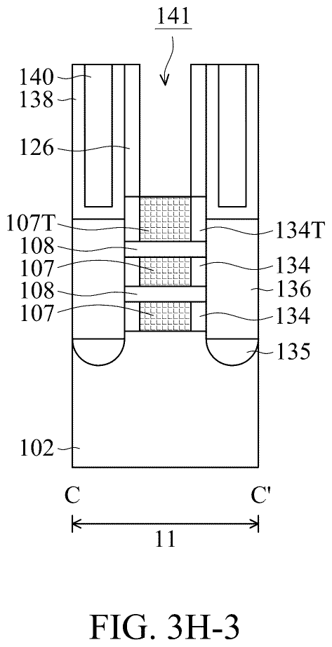

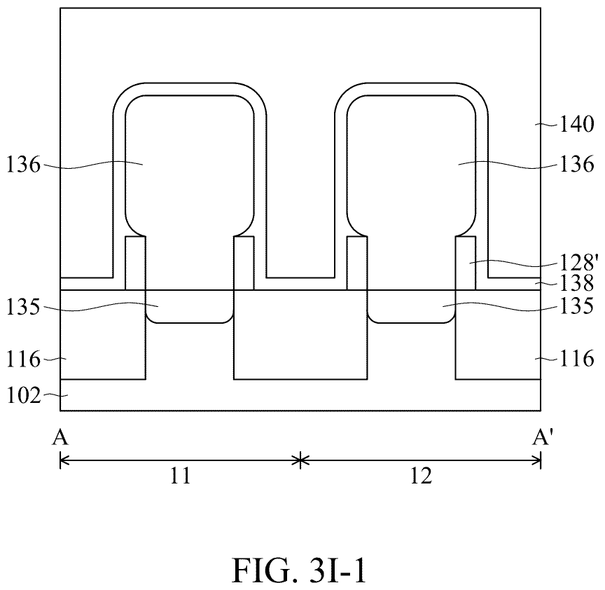

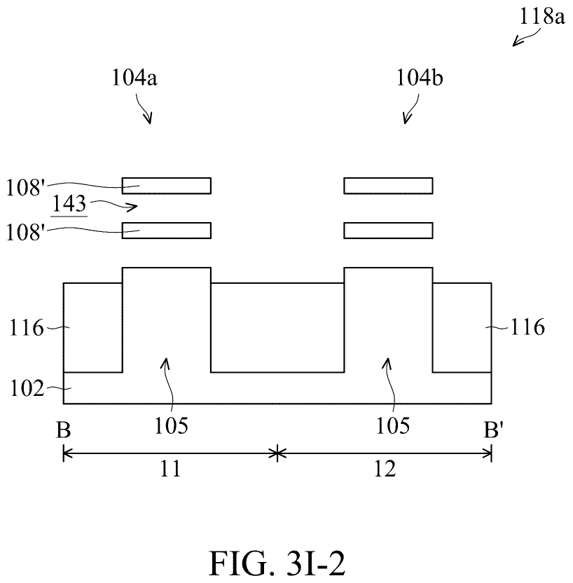

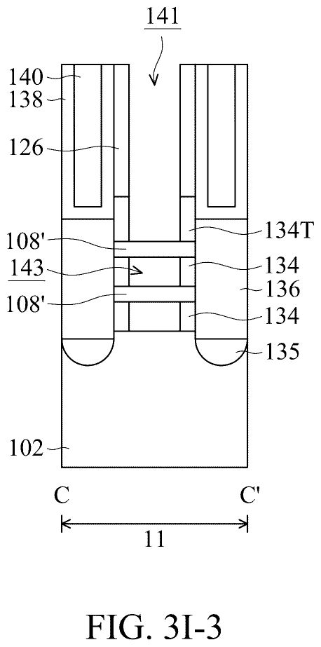

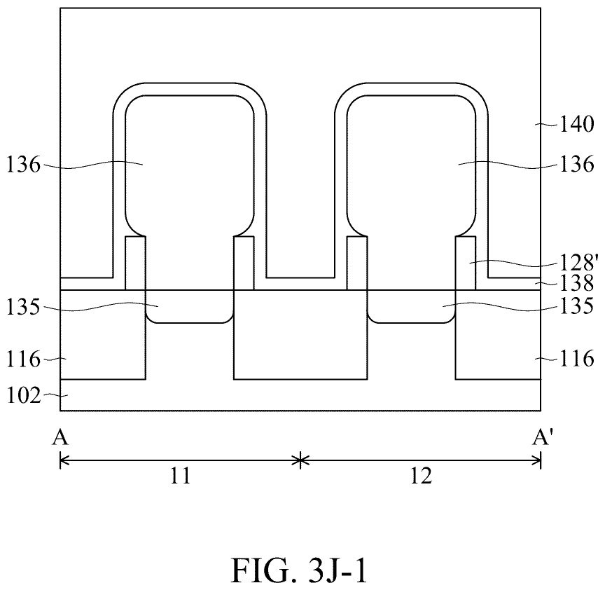

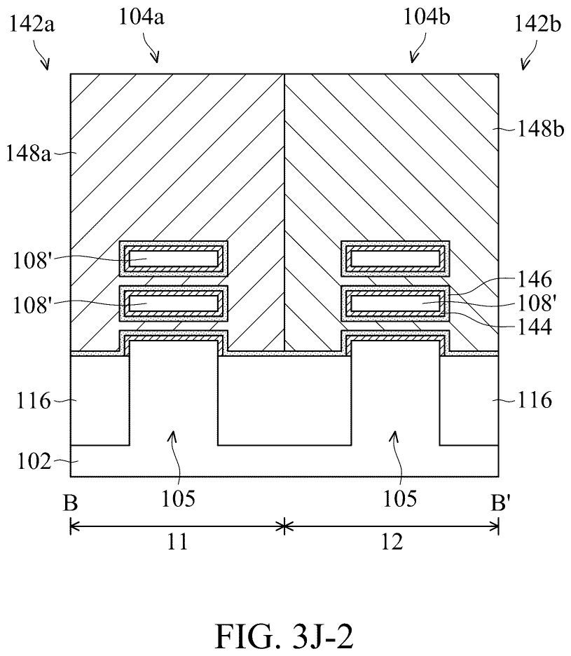

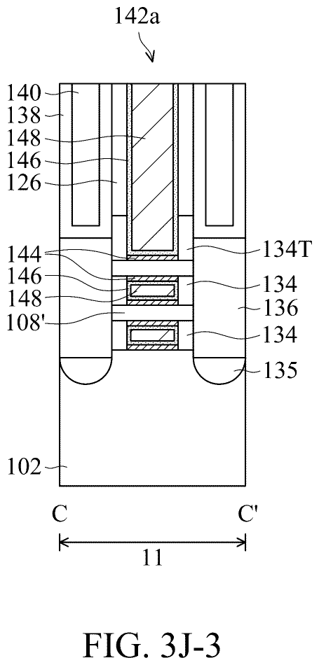

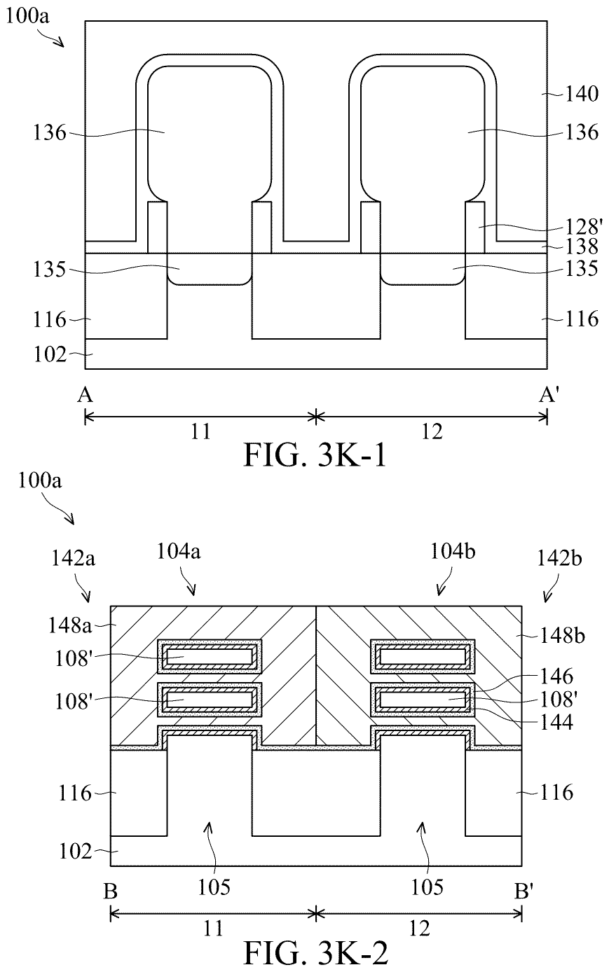

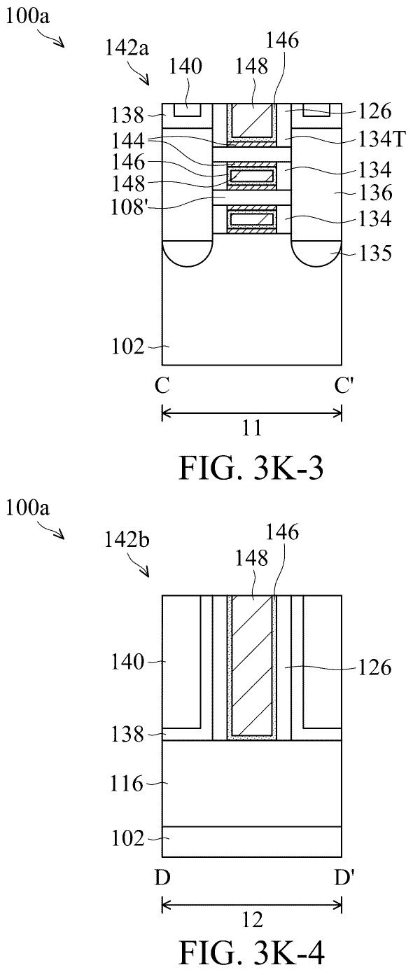

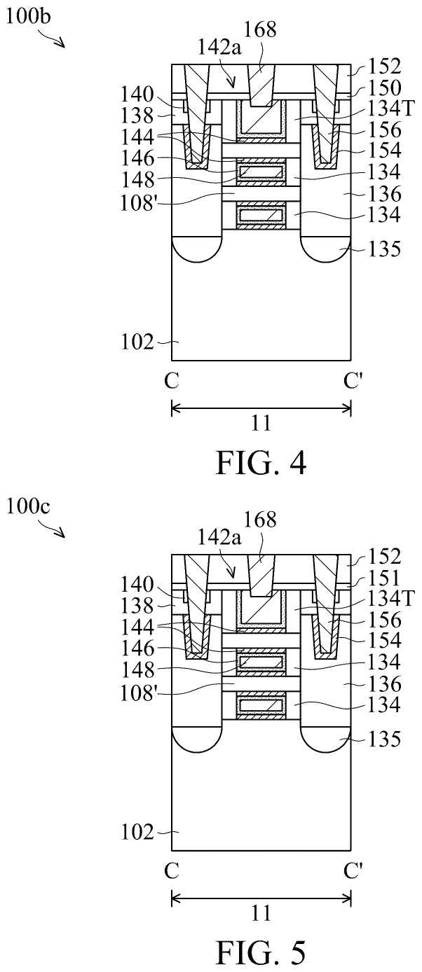

FIGS. 3A-1 to 3K-1 illustrate cross-sectional representations of various stages of manufacturing the semiconductor structure 100a shown along line A-A′ in FIG. 1E and in FIG. 2, in accordance with some embodiments. FIGS. 3A-2 to 3K-2 illustrate cross-sectional representations of various stages of manufacturing the semiconductor structure 100a shown along line B-B′ in FIG. 1E and in FIG. 2, in accordance with some embodiments. FIGS. 3A-3 to 3K-3 illustrate cross-sectional representations of various stages of manufacturing the semiconductor structure 100a shown along line C-C′ in FIG. 1E and in FIG. 2, in accordance with some embodiments. FIG. 3K-4 illustrate cross-sectional representations of various stages of manufacturing the semiconductor structure 100a shown along line D-D′ in FIG. 1E and in FIG. 2, in accordance with some embodiments.

More specifically, FIG. 3A-1 illustrates the cross-sectional representation shown along line A-A″ in FIG. 1E and FIG. 2. FIG. 3A-2 illustrates the cross-sectional representation shown along line B-B′ in FIG. 1E and FIG. 2 in accordance with some embodiments. FIG. 3A-3 illustrates the cross-sectional representation shown along line C-C′ in FIG. 1E and in FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, the first fin structure 104a and the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2 and 3C-3, after the source/drain (S/D) recesses 130 are formed, the topmost first semiconductor material layer 106T and first semiconductor material layers 106 are replaced with dummy dielectric layers 107, as shown in in accordance with some embodiments. As a result, the second semiconductor material layers 108 and the dummy dielectric layer 107 are alternately stacked. The topmost dummy dielectric layer 107T is formed on the top of the dummy dielectric layer 107. The thickness of the topmost dummy dielectric layer 107T is greater than the thickness of the other dummy dielectric layer 107. The dummy dielectric layer 107 is also called as disposable interposer which will be removed and replaced with a first gate structure 142a and a second gate structure 142b (shown in FIGS. 3J-1, 3J-2 and 3J-3) in the following steps.

The dummy dielectric layer 107 is made of silicon oxide (SiO₂), silicon oxynitride (SiON), aluminum oxide (Al₂O₃) or another applicable materials. In some embodiments, the dummy dielectric layer 107 is formed by an ALD (atomic layer deposition process), flowable CVD or another application process.

Afterwards, as shown in FIGS. 3D-1, 3D-2 and 3D-3, after dummy dielectric layers 107 are formed, a portion of the dummy dielectric layer 107 exposed by the source/drain recesses 130 are laterally recessed to form notches 132, in accordance with some embodiments.

In some embodiments, an etching process is performed on the semiconductor structure 100a to laterally recess the dummy dielectric layer 107 of the fin structure 104a/104b from the source/drain recesses 130.

In some embodiments, during the etching process, the dummy dielectric layer 107 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3E-1, 3E-2 and 3E-3, inner spacers 134 are formed in the notches 132 between the second semiconductor material layers 108, in accordance with some embodiments. The inner spacer layers 134 and the gate spacer layer 126 are made of different materials, and the dielectric constant (k value) of the gate space layer 126 is lower than the dielectric constant (k value) of the inner spacer layer 134. The topmost inner spacer layer 134T is on the top. The thickness of the topmost inner spacer layer 134T is greater than the thickness of the other inner spacer layer 134.

The inner spacers 134 are configured to separate the source/drain (S/D) structures and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 3F-1, 3F-2 and 3F-3, after the inner spacers 134 are formed, a bottom layer 135 and source/drain (S/D) structures 136 are formed in the S/D recesses 130, in accordance with some embodiments.

In some embodiments, the top surface of the topmost inner spacer layer 134T is higher than the top surface of the source/drain (S/D) structures 136. In some other embodiments, the top surface of the topmost inner spacer layer 134T is lower than the top surface of the source/drain (S/D) structures 136.

In some embodiments, the bottom layer 135 include un-doped Si, un-doped SiGe or a combination thereof. In some embodiments, the bottom layer 135 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the source/drain (S/D) structures 136 are in-situ doped during the epitaxial growth process. For example, the source/drain (S/D) structures 136 may be the epitaxially grown SiGe doped with boron (B). For example, the first source/drain (S/D) structures 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain (S/D) structure 136 is doped in one or more implantation processes after the epitaxial growth process.

Afterwards, as shown in FIGS. 3G-1, 3G-2 and 3G-3, a contact etch stop layer (CESL) 138 is conformally formed to cover the S/D structures 136 and an interlayer dielectric (ILD) layer 140 is formed over the contact etch stop layers 138, in accordance with some embodiments. The top surface of the topmost inner spacer layer 134T is higher than the bottom surface of the CESL 138. In addition, the top surface of the topmost inner spacer layer 134T is higher than the bottom surface of ILD layer 140.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layers 120 of the dummy gate structures 118 are exposed, as shown in FIG. 3I-3 in accordance with some embodiments.

Afterwards, as shown in FIGS. 3H-1, 3H-2 and 3H-3, the first dummy gate structure 118a and the second dummy gate structure 118b are removed to form a trench 141, in accordance with some embodiments. As a result, the first fin structure 104a and the second fin structure 104b are exposed by the trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, as shown in FIGS. 3I-1, 3I-2 and 3I-3, the topmost dummy dielectric layer 107T and the dummy dielectric layer 107 are removed to form nanostructures 108′ (or channel layers 108′) with the second semiconductor material layers 108, in accordance with some embodiments. As a result, the gaps 143 are between the nanostructures 108′ (or channel layers 108′).

Next, as shown in FIGS. 3J-1, 3J-2 and 3J-3, after the nanostructures 108′ are formed, a first gate structure 142a and a second gate structure 142b are formed to surround the nanostructures 108′ and over the isolation structure 116, in accordance with some embodiments.

After the nanostructures 108′ are formed, the first gate structure 142a and the second gate structure 142b are formed wrapped around the nanostructures 108′. The first gate structure 142a and the second gate structure 142b wrap around the nanostructures 108′ to form gate-all-around transistor structures in accordance with some embodiments. In some embodiments, the first gate structure 142a includes an interfacial layer 144, a gate dielectric layer 146, and a gate electrode layer 148a. In some embodiments, the second gate structure 142b includes an interfacial layer 144, a gate dielectric layer 146, and a gate electrode layer 148b.

In some embodiments, the interfacial layers 144 are oxide layers formed around the nanostructures 108′ and on the top of the base fin structure 105. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacers 126 and the inner spacers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layers 148a and the gate electrode layers 148b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 148a and gate electrode layers 148b are formed using chemical vapor deposition (CVD), atomic layer deposition (ALD), electroplating, another applicable method, or a combination thereof. Other conductive layers, such as work function metal layers, may also be formed in the first gate structure 142a and the second gate structure 142b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layers 148a and gate electrode layers 148b are formed, a planarization process such as CMP or an etch-back process may be performed until the ILD layer 140 is exposed.

Afterwards, as shown in FIGS. 3K-1, 3K-2 and 3K-3, the top portions of the first gate structure 142a and the second gate structure 142b are removed, and all of the gate spacer layers 126 directly on the nanostructures 108′ are removed, in accordance with some embodiments. As a result, the top surface of the first gate structure 142a and the second gate structure 142b are substantially coplanar with the top surface of the topmost inner spacer layer 134T. In addition, the top surface of the topmost inner spacer layers 134T is exposed. In some embodiments, the top portions of the first gate structure 142a, the top portions of the second gate structure 142b and the gate spacer layers 126 are removed by a polishing process, such as CMP (Chemical-Mechanical Planarization) process.

When the dummy gate structures 118a/118b are removed (shown in FIG. 3H-3) to form trench 141, a bottom portion of the gate spacer layer 126 may be removed. As a result, the trench 141 may have wider bottom portions, not have vertical sidewall surfaces. When the first gate structure 142a and the second gate structure 142b are filled into the trench 141, the first gate structure 142a and the second gate structure 142b may have footing profile. The footing profile of the gate structure may degrade the performance of the semiconductor structure.

In order to prevent the unwanted footing issue, the top portions of the second gate structure 142b and the gate spacer layers 126 are removed. As a result, the profiles of the first gate structure 142a and the second gate structure 142b, the top portions of the first gate structure 142a are improved. Therefore, the sidewall surface of the topmost first gate structure 142a and topmost the second gate structure 142b is aligned with the sidewall surface of the middle first gate structure 142a, the sidewall surface of the middle second gate structure 142b, and the sidewall surface of the bottommost first gate structure 142a and the sidewall surface of the bottommost the second gate structure 142b. In other words, the profile of the topmost first gate structure 142a and topmost the second gate structure 142b is substantially the same with the profile of the bottommost first gate structure 142a and bottommost the second gate structure 142b. When the uniformity of the profiles of the gate structure (142a/142b) are improved, the variation of threshold voltage (Vt) of the semiconductor structure 100a and the variation of the DIBL (Drain Induced Barrier Lowering) are improved. Therefore, the performance of the semiconductor structure 100a is improved.

It should be noted that the top surface of the topmost inner spacer layer 134T is higher than the top surface of the topmost nanostructure 108′. The top surface of the first gate structure 142a and the second gate structure 142b are substantially coplanar with the top surface of the topmost inner spacer layers 134T. No gate spacer layer is left on the topmost inner spacer layer 134T. The gate spacer layer 126 and the inner spacer layer 134 are made of different materials. The dielectric constant (k value) of the gate spacer layer 126 is lower than the dielectric constant (k value) of the inner spacer layer 134. Therefore, the polishing process can stop on the inner spacer layer 134.

Furthermore, the thickness of the topmost inner spacer layer 134T is greater than the thickness of the bottommost inner spacer layer 134 since the thickness of the topmost first semiconductor material layer 106T is greater than the thickness of the other first semiconductor material layer 106. In addition, the top surface of the topmost inner spacer layer 134T is higher than the bottom surface of the ILD layer 140.

FIG. 3K-4 illustrate cross-sectional representations of various stages of manufacturing the semiconductor structure 100a shown along line D-D′ in FIG. 1E and in FIG. 2, in accordance with some embodiments.

As shown in FIG. 3JK-4, the second gate structure 142b is formed on the isolation structure 116. The gate spacer layer 126 is formed on the sidewall surfaces of the second gate structure 142b. It should be noted that although the gate spacer layer 126 directly on the nanostructures 108′ (or channel layers 108′) are removed, the gate spacer layer 126 directly on the isolation structure 116 is not removed.

It should be noted that the top portions of the first gate structure 142a, the top portions of the second gate structure 142b and the gate spacer layers 126 are removed. As a result, the profile of the first gate structure 142a and the second gate structure 142b are improved. The sidewall surface of the topmost first gate structure 142a and topmost the second gate structure 142b is aligned with the sidewall surface of the bottommost first gate structure 142a and the sidewall surface of the bottommost the second gate structure 142b. In other words, the profile of the topmost first gate structure 142a and topmost the second gate structure 142b is substantially the same with the profile of the bottommost first gate structure 142a and bottommost the second gate structure 142b. The unwanted footing issue of the gate structure is prevented. When the uniformity of the profiles of the gate structure are improved, the variation of threshold voltage (Vt) of the semiconductor structure 100a and the variation of the DIBL (Drain Induced Barrier Lowering) are improved. Therefore, the performance of the semiconductor structure 100a is improved.

FIG. 4 illustrate a cross-sectional representation of manufacturing a semiconductor structure 100b after FIG. 3K-3, in accordance with some embodiments. The semiconductor structure 100b of FIG. 4 includes elements that are similar to, or the same as, elements of the semiconductor structure 100a of FIGS. 3A-1 to 3K-1, 3A-2 to 3K-2 and 3A-3 to 3K-3.

As shown in FIG. 4, an etch stop layer 150 is formed over the gate structure 142, and a dielectric layer 152 is formed over the etch stop layer 150, in accordance with some embodiments. Next, a silicide layer 154 and an S/D contact structure 156 are formed over the S/D structure 136, in accordance with some embodiments. The S/D contact structure 156 is electrically connected to the S/D structure 136. A gate conductive plug 168 is formed over and electrically connected to the first gate structure 142a and the second gate structure 142b.

The bottom surface of the S/D contact structure 156 is lower than the top surface of the topmost inner spacer layer 134T. In addition, the CESL 138 is in contact with the topmost inner spacer layer 134T. More specifically, the bottom surface of the CESL 138 is lower than the top surface of the topmost inner spacer layer 134T. The topmost inner spacer layer 134T is in contact with the interface between the CESL 138 and the S/D structure 136.

In addition, the etch stop layer 150 is formed on the first gate structure 142a, the inner spacer layer 134 and the S/D structure 136, and the etch stop layer 150 is in contact with the inner spacer layer 134. Therefore, the topmost inner spacer layer 134T is in direct contact with the etch stop layer 150 and the CESL 138.

In some embodiments, the etch stop layer 150 is made of a dielectric materials, such as silicon nitride, silicon oxide, silicon oxynitride, another suitable dielectric material, or a combination thereof. The dielectric material for the etch stop layers 150 may be conformally deposited over the semiconductor structure by performing chemical vapor deposition (CVD), ALD, other application methods, or a combination thereof.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes.

The silicide layers 154 may be formed by forming a metal layer over the top surfaces of the S/D structure 136 and annealing the metal layer so the metal layer reacts with the S/D structure 136 to form the silicide layers 154. The unreacted metal layer may be removed after the silicide layers 154 are formed.

The S/D contact structure 156 may include a barrier layer and a conductive layer. In some other embodiments, the S/D contact structure 156 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

In some embodiments, the gate conductive plug 168 is made of conductive material, such as tungsten (W), ruthenium (Ru), molybdenum (Mo), or the like. In some embodiments, the gate conductive plug 168 is formed by performing a deposition process, such as chemical vapor deposition (CVD), physical vapor deposition, (PVD), atomic layer deposition (ALD), or other applicable processes.

FIG. 5 illustrate a cross-sectional representation of a semiconductor structure 100c after FIG. 3K-3, in accordance with some embodiments. The semiconductor structure 100c of FIG. 5 includes elements that are similar to, or the same as, elements of the semiconductor structure 100a of FIGS. 3A-1 to 3K-1, 3A-2 to 3K-2 and 3A-3 to 3K-3.

In addition, the semiconductor structure 100c of FIG. 5 is similar to the semiconductor structure 100b of FIG. 4, the difference between the FIG. 5 and FIG. 4 is that the S/D contact structure 156 does not pass through the etch stop layer 151. The top surface of the etch stop layer 151 is higher than the top surface of the S/D contact structure 156. The etch stop layer 150 is removed by a CMP process when the S/D contact structure 156 is polished. Next, the etch stop layer 151 is formed after the S/D contact structure 156 is formed and polished. In FIG. 4, the etch stop layer 150 is formed before the S/D contact structure 156 is formed. In FIG. 5, the etch stop layer 151 is formed after the S/D contact structure 156 is formed.

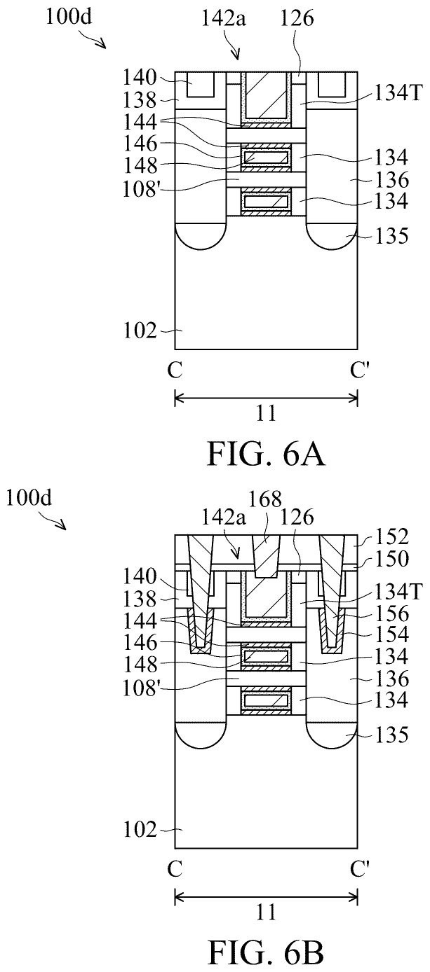

FIGS. 6A to 6B illustrate cross-sectional representations of various stages of manufacturing a semiconductor structure 100d, in accordance with some embodiments. The semiconductor structure 100d of FIGS. 6A-6B includes elements that are similar to, or the same as, elements of the semiconductor structure 100a of FIGS. 3A-1 to 3K-1, 3A-2 to 3K-2 and 3A-3 to 3K-3.

The semiconductor structure 100d of FIG. 6A is similar to the semiconductor structure 100a of FIG. 3K-3, the difference between the FIG. 6 and FIG. 3K-3 is that a remaining gate spacer layer 126 is left on the topmost inner spacer layer 134T. The height of the gate spacer layer 126 is less than the height of the topmost inner spacer layer 134T in a vertical direction.

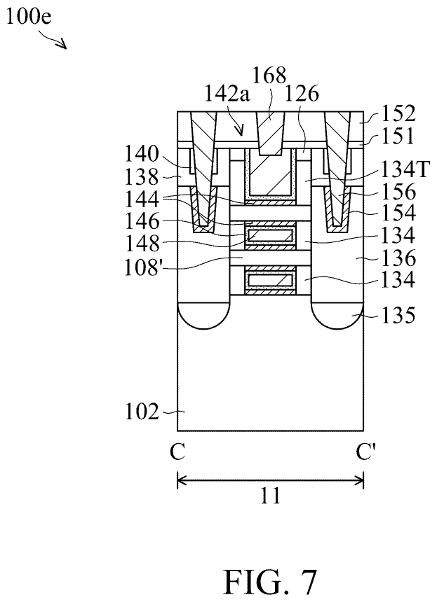

FIG. 7 illustrates a cross-sectional representation of a semiconductor structure 100e, in accordance with some embodiments. The semiconductor structure 100e of FIG. 7 includes elements that are similar to, or the same as, elements of the semiconductor structure 100d of FIG. 6B. The difference between the FIG. 7 and FIG. 6B is that the S/D contact structure 156 does not pass through the etch stop layer 151. The top surface of the etch stop layer 151 is higher than the top surface of the S/D contact structure 156.

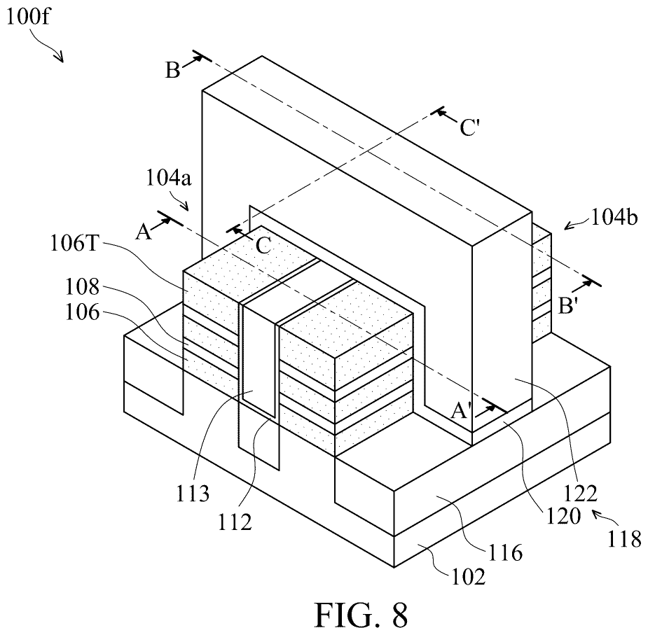

FIG. 8 shows a perspective view of a semiconductor structure 100f, in accordance with some embodiments. The semiconductor structure 100f of FIG. 8 includes elements that are similar to, or the same as, elements of the semiconductor structure 100a of FIGS. 3A-1 to 3K-1, 3A-2 to 3K-2 and 3A-3 to 3K-3.

As shown in FIG. 8, the first fin structure 104a and the second fin structure 104b are formed over the substrate 102. The first fin structure 104a includes first semiconductor material layers 106 and second semiconductor material layers 108 alternatively stacked. The second fin structure 104b includes first semiconductor material layers 106 and second semiconductor material layers 108 alternatively stacked. The topmost first semiconductor material layer 106T is on the top of the first semiconductor material layer 106. The thickness of the topmost first semiconductor material layer 106T is greater than the thickness of the other first semiconductor material layer 106.

After the first fin structure 104a and the second fin structure 104b are formed, the isolation structure 116 is formed around the first fin structure 104a and the second fin structure 104b.

Next, a liner dielectric layer 112 is formed over the first fin structure 104a and the second fin structure 104b, and a core dielectric layer 113 is formed over the liner dielectric layer 112. The liner dielectric layer 112 is an adhesion layer to improve the adhesion between the core dielectric layer 113 and the first fin structure 104a and the second fin structure 104b.

Next, a portion of the liner dielectric layer 112 and a portion of the core dielectric layer 113 are removed to form a dielectric wall 115 between two adjacent first fin structure 104a and the second fin structure 104b, in accordance with some embodiments. More specifically, the dielectric wall 115 is in direct contact with the first semiconductor layers 106 and the second semiconductor layers 108. The dielectric wall 115 is in direct contact with the isolation structure 116.

In some embodiments, the liner dielectric layer 112 is made of oxide, such as silicon oxide. In some embodiments, the liner dielectric layer 112 is formed by chemical vapor deposition (CVD), atomic vapor deposition (ALD), physical vapor deposition (PVD), another suitable method, or a combination thereof. In some embodiments, the core dielectric layer 113 is made of SiN, SiCN, SiOC, SiOCN or applicable material. In some embodiments, the core dielectric layer 113 is formed by chemical vapor deposition (CVD), atomic vapor deposition (ALD), physical vapor deposition (PVD), another suitable method, or a combination thereof.

After the dielectric wall 115 is formed, the dummy gate structure 118 is formed across the first fin structure 104a and the second fin structure 104b and extends over the isolation structure 116, in accordance with some embodiments.

The dummy gate structures 118 may be used to define the source/drain (S/D) regions and the channel regions of the resulting semiconductor structure 100f. In some embodiments, the dummy gate structures 118 include the dummy gate dielectric layer 120 and the dummy gate electrode layer 122.

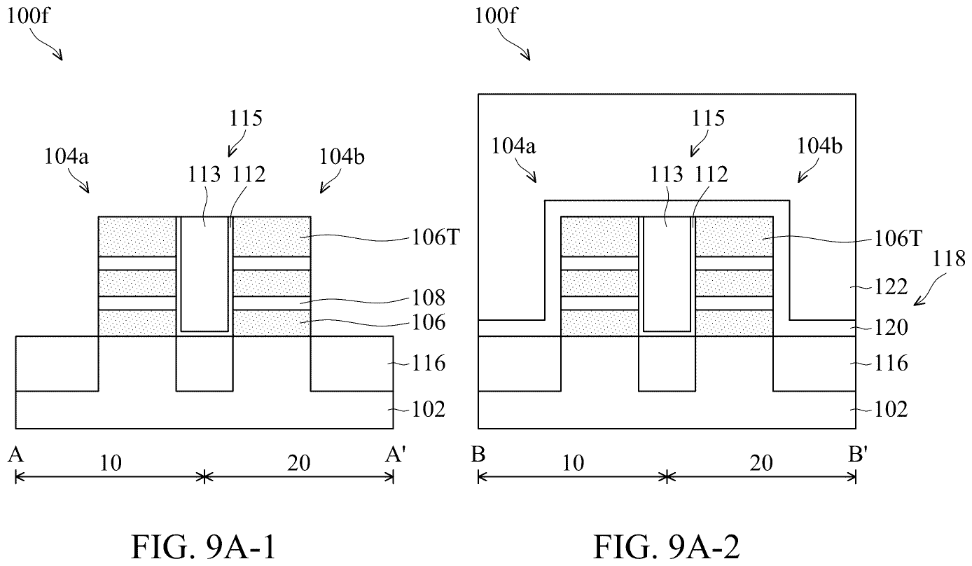

FIG. 9A-1 shows the cross-sectional representation of various stages of manufacturing the semiconductor structure 100f shown along line A-A′ in FIG. 8, in accordance with some embodiments. FIG. 9A-2 shows the cross-sectional representation of various stages of manufacturing the semiconductor structure 100f shown along line B-B′ in FIG. 8, in accordance with some embodiments. FIG. 9A-1 shows an S/D region and FIG. 9A-2 shows a gate structure region.

As shown in FIGS. 9A-1 and 9A-2, the substrate 102 includes a first region 10 and a second region 20. The first fin structure 104a is formed in the first region 10, and the second fin structure 104b is formed in the second region 20. The dielectric wall 115 is between and in direct contact with the first fin structure 104a and the second fin structure 104b. The liner dielectric layer 112 is in direct contact with the first semiconductor layers 106 and the second semiconductor layers 108. The liner dielectric layer 112 has a U-shaped structure. The dummy gate structure 118 is formed across the first fin structure 104a and the second fin structure 104b and over the dielectric wall 115. The dummy gate structure 118 includes the dummy gate dielectric layer 120 and the dummy gate electrode layer 122.

Next, the semiconductor structure 100f may undergo the various processes that are similar to the processes shown in FIGS. 3A-1 to 3K-1, 3A-2 to 3K-2 and 3A-3 to 3K-3 to form semiconductor structure 100f in FIGS. 10A-1, 10A-2 and 10A-3.

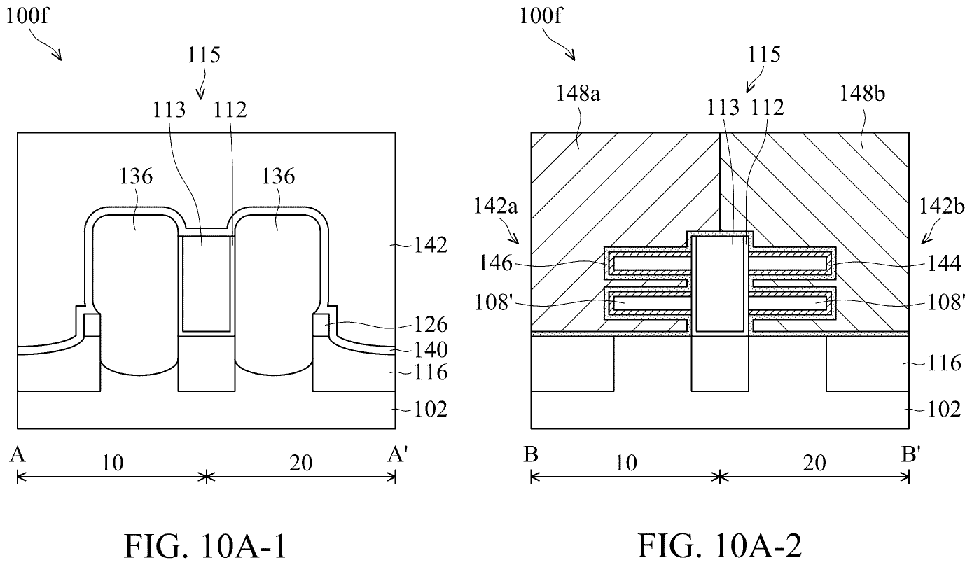

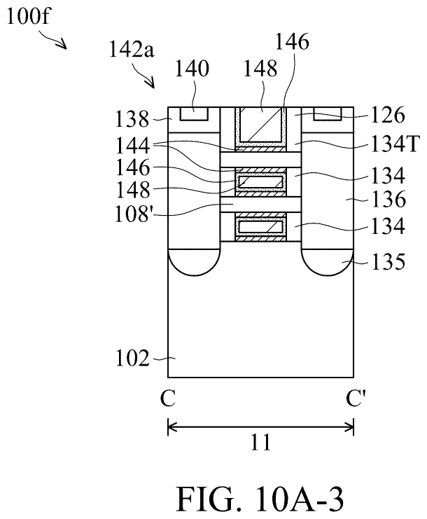

FIG. 10A-1 shows a cross-sectional representation of various stages of manufacturing the semiconductor structure 100f shown along line A-A′ in FIG. 8, in accordance with some embodiments. FIG. 10A-2 shows a cross-sectional representation of various stages of manufacturing the semiconductor structure 100f shown along line B-B′ in FIG. 8, in accordance with some embodiments. FIG. 10A-3 shows a cross-sectional representation of various stages of manufacturing the semiconductor structure 100f shown along line C-C′ in FIG. 8, in accordance with some embodiments.

As shown in FIG. 10A-1, the S/D structures 136 are formed in the first region 10 and the second region 20, in accordance with some embodiments. The top surface of the dielectric wall 115 is lower than the top surfaces of the S/D structures 138. After the S/D structures 138 are formed, the contact etch stop layer (CESL) 138 is conformally formed to cover the S/D structures 136 and the interlayer dielectric (ILD) layer 140 is formed over the contact etch stop layers 138, in accordance with some embodiments.

As shown in FIG. 10A-2, the first gate electrode layer 142a is formed in the first region 10 to surround the nanostructures 108′, and the second gate electrode layer 142b is formed in the second region 20 to surround the nanostructures 108′, in accordance with some embodiments.

The first gate structure 142a is constructed by the interfacial layer 144, the gate dielectric layer 146, and the first gate electrode layer 148a. The second gate structure 142b is constructed by the interfacial layer 144, the gate dielectric layer 146, and the second gate electrode layer 148b. The material of the second gate electrode layer 148b is different from that of the first gate electrode layer 148a. There is an interface between the first gate electrode layer 148a and the second gate electrode layer 148b.

As shown in FIG. 10A-3, similar to the processes shown in FIG. 3K-3, after the polishing process, the top portions of the first gate structure 142a and the second gate structure 142b are removed, and all of the gate spacer layers 126 directly on the nanostructures 108′ are removed, in accordance with some embodiments. As a result, the top surface of the first gate structure 142a and the second gate structure 142b are substantially coplanar with the top surface of the topmost inner spacer layer 134T. The silicide and the S/D contact structure may be formed on the S/D structure 136 similar to FIGS. 4 and 5.

Note that the gate spacer layers 126 directly on the isolation structure 116 is not removed, and the gate spacer layers 126 is still remaining direct on and in contact with the isolation structure 116. The topmost inner spacer layer 134T is in direct contact with the interface between the S/D structure 136 and the CESL 138.

The top portions of the second gate structure 142b and the gate spacer layers 126 are removed. As a result, the profiles of the first gate structure 142a and the second gate structure 142b, the top portions of the first gate structure 142a are improved. When the uniformity of the profiles of the gate structure are improved, the variation of threshold voltage (Vt) of the semiconductor structure 100f and the variation of the DIBL (Drain Induced Barrier Lowering) are improved. Therefore, the performance of the semiconductor structure 100f is improved.

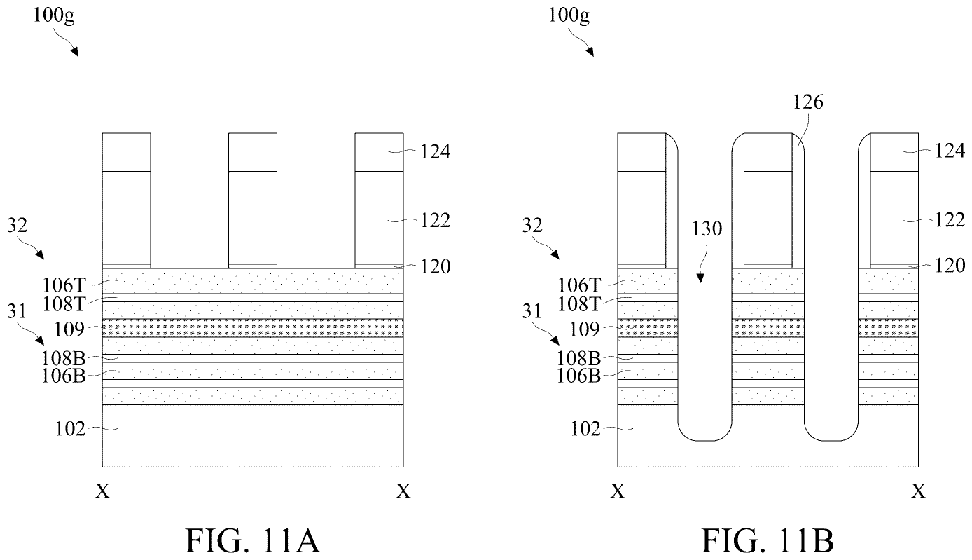

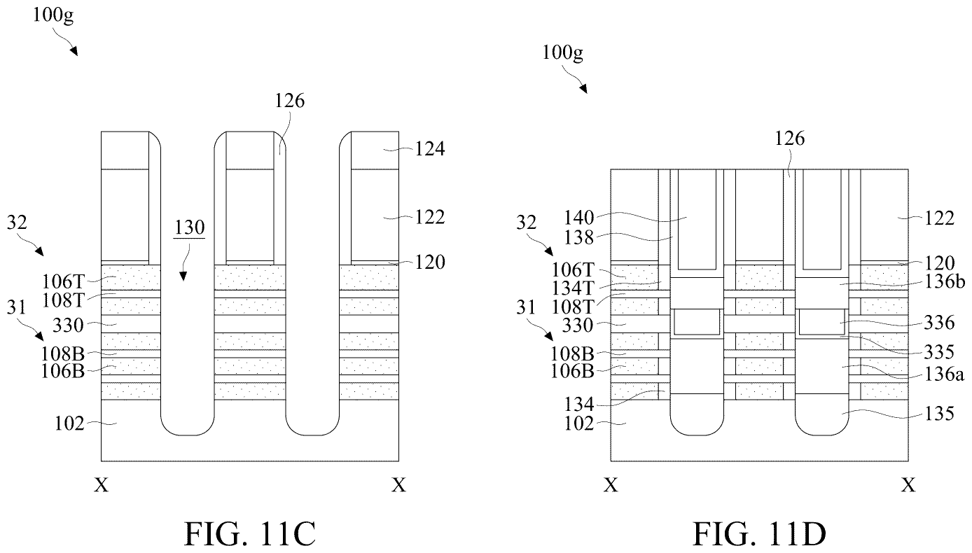

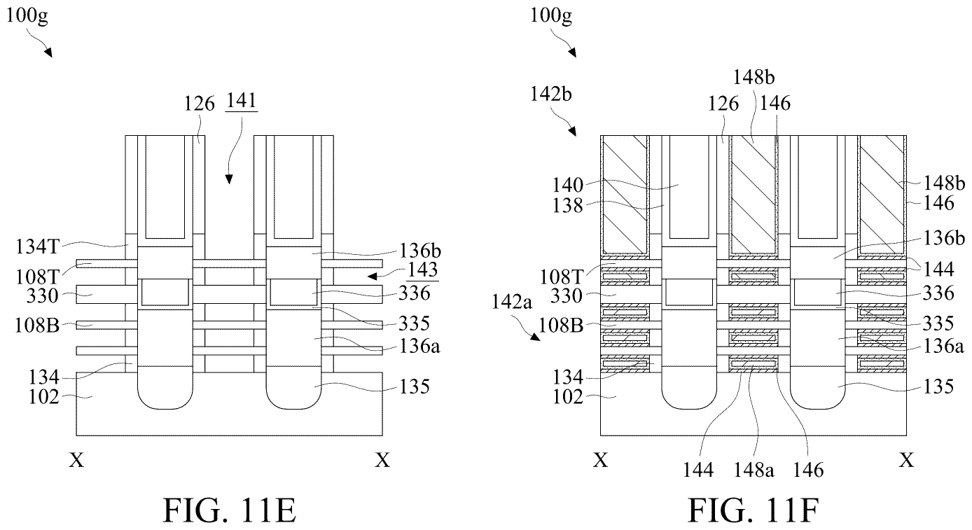

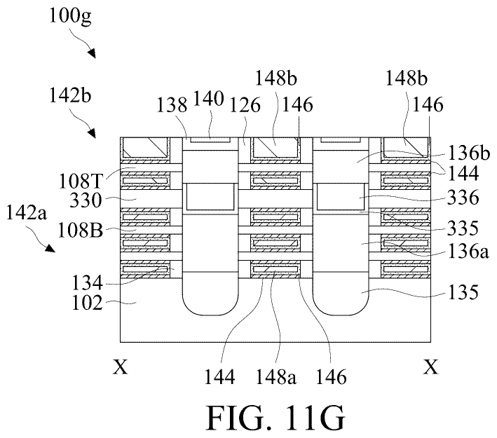

FIGS. 11A to 11G illustrate cross-sectional representations of various stages of manufacturing a semiconductor structure 100g, in accordance with some embodiments.

As shown in FIG. 11A, a first stack structure 31 is formed over the substrate 102, a sacrificial layer 109 is formed over the first stack structure 31 and a second stack structure 32 is formed over the sacrificial layer 109, in accordance with some embodiments. The semiconductor structure 100g is used to form CFET devices in which n-type devices and p-type devices are stacked.

The first stack structure 31 includes the first semiconductor layers 106B and the second semiconductor layers 108B are alternatively stacked. The second stack structure 32 includes the first semiconductor layers 106T and the second semiconductor layers 108T are alternatively stacked. The sacrificial layer 109 is made of first semiconductor layers. The first semiconductor layers 106B and the second semiconductor layers 108B are made of different materials. The first semiconductor layers 106T and the second semiconductor layers 108T are made of different materials.

In some embodiments, the first semiconductor material layers 106B, 106T are made of SiGe, and the second semiconductor material layers 108B, 108T are made of silicon. In some embodiments, the sacrificial layer 109 is made of SiGe.

The first stack structure 31 and the second stack structure 32 are formed using an epitaxial growth process, in accordance with some embodiments. The epitaxial growth process may be molecular beam epitaxy (MBE), metal organic chemical vapor deposition (MOCVD), vapor phase epitaxy (VPE), or another suitable technique.

The sacrificial layer 109 will be replaced with dielectric layer (shown in FIG. 11C). The first semiconductor layers 106B and 106T and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments.

The dummy gate structures 118 are formed across the first stack structure 31, the sacrificial layer 109 and the second stack structure 32. In some embodiments, the dummy gate structures 118 extend in the second direction (e.g. Y-axis). That is, the dummy gate structures 118 have longitudinal axes parallel to the second direction (e.g. Y-axis), in accordance with some embodiments. The dummy gate structures 118 are configured as sacrificial structures and will be replaced with the final gate stacks, in accordance with some embodiments

The dummy gate structures 118 may be used to define the source/drain (S/D) regions and the channel regions of the resulting semiconductor structure 100g. In some embodiments, the dummy gate structure 118 include dummy gate dielectric layers 120 and dummy gate electrode layers 122.

Afterwards, as shown in FIG. 11B, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

After the gate spacer layers 126 and the fin spacer layers 128 are formed, the source/drain (S/D) regions of the fin structure 104 are recessed to form source/drain (S/D) recesses 130, as shown in in accordance with some embodiments.

Next, as shown in FIG. 11C, the sacrificial layer 109 is removed to form a recess (not shown), and then a middle dielectric layer 330 is formed in the recess and in the S/D recess 130, in accordance with some embodiments. Next, a portion of the middle dielectric layer 330 outside of the recess 130 is removed.

It should be noted that the middle dielectric layer 330 and the gate spacer layer 126 are made of different materials. The middle dielectric layer 330 has a high etching selectivity with respect to the gate spacer layer 126. When the middle dielectric layer 330 is removed while the gate spacer layer 126 is not removed in the following process.

In some embodiments, the middle dielectric layer 330 is made of silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the middle dielectric layer 330 is formed by a chemical vapor deposition (CVD), atomic vapor deposition (ALD), physical vapor deposition (PVD), or another suitable process.

Afterwards, as shown in FIG. 11D, after the middle dielectric layer 330 are formed, the first semiconductor layers 106B, 106T exposed by the S/D (source/drain) recesses 130 are laterally recessed to form notches (not shown), and inner spacer layers 134 are formed in the notches between the second semiconductor layers 108B, 108T, in accordance with some embodiments. The thickness of the topmost inner spacer layer 134T is greater than the thickness of the other inner spacer layer 134.

The inner spacer layers 134 are configured to separate the source/drain (S/D) structures and the gate structures formed in subsequent manufacturing processes in accordance with some embodiments.

Next, the bottom layer 135 is formed in the S/D recess 130, a first S/D structure 136a is formed on the bottom layer 135, and a contact etching stop layer 335 and a spacer dielectric layer 336 are formed on the first S/D structure 136a. Next, a second S/D structure 136b is formed on the spacer dielectric layer 336.

Afterwards, the CESL 138 is formed over the second S/D structure 136b, and the ILD layer 140 is formed on the CESL 138, in accordance with some embodiments.

Next, as shown in FIG. 11E, the dummy gate electrode layer 122 and the first dummy gate dielectric layer 120 are removed to form a trench 141, and the first semiconductor layer 106B and 106T are removed to form a number of gaps 143, in accordance with some embodiments.

As a result, the nanostructures 108B and 108T (or channel layers 108B and 108T) with the second semiconductor material layers 108 are obtained. The number of nanostructures 108B and 108T (or channel layers 108B and 108T) may be adjusted according to actual application. In addition, the middle dielectric layer 330 is exposed by the trench 141 and the gaps 143.

After the nanostructures 108B and 108T are formed, the first gate structure 142a and the second gate structure 142b are formed to surround the nanostructures 108B and 108T and over the isolation structure 116, in accordance with some embodiments.

The first gate structure 142a is a first type gate structure, and the second gate structure 142b is a second type gate structure. In some embodiments, the first gate structure 142a is an N-type gate structure, and the second gate structure 142b is a P-type gate structure. In some embodiments, the first gate structure 142a is a P-type gate structure, and the second gate structure 142b is an N-type gate structure. The first gate structure 142a and the second gate structure 142b extend in the second direction (e.g. Y-axis). The first gate structure 142a and the second gate structure 142b have longitudinal axes parallel to the Y direction, in accordance with some embodiments.

The first gate structure 142a includes the interfacial layer 144, the gate dielectric layer 146, and the first gate electrode layer 148a. The second gate structure 142b includes the interfacial layer 144, the gate dielectric layer 146, and the second gate electrode layer 148b.

Afterwards, as shown in FIG. 11G, the top portions of the second gate structure 142b are removed, and all of the gate spacer layers 126 are removed, in accordance with some embodiments. As a result, the top surface of the second gate structure 142b is substantially coplanar with the top surface of the topmost inner spacer layer 134T. In addition, the top surface of the topmost inner spacer layers 134T is exposed. In some embodiments, the top portions of the top portions of the second gate structure 142b and the gate spacer layers 126 are removed by a polishing process, such as CMP (Chemical-Mechanical Planarization) process. Next, the silicide and the S/D contact structure may be formed on the second S/D structure 136b similar to FIGS. 4 and 5.

It should be noted that the top surface of the topmost inner spacer layer 134T is higher than the top surface of the topmost nanostructure 108T. The topmost inner spacer layer 134T is in direct contact with the CESL 138. In other words, the topmost inner spacer layer 134T is in direct contact with the interface between the CESL 138 and the S/D structure 136b.

It should be noted that the top portions of the second gate structure 142b and the gate spacer layers 126 are removed. As a result, the profile of the second gate structure 142b is improved. The sidewall surface of topmost the second gate structure 142b is aligned with the sidewall surface of the bottommost first gate structure 142a and the sidewall surface of the bottommost the second gate structure 142b The unwanted footing issue of the gate structure is prevented. When the uniformity of the profiles of the gate structure are improved, the variation of threshold voltage (Vt) of the semiconductor structure 100g and the variation of the DIBL (Drain Induced Barrier Lowering) are improved. Therefore, the performance of the semiconductor structure 100g is improved.

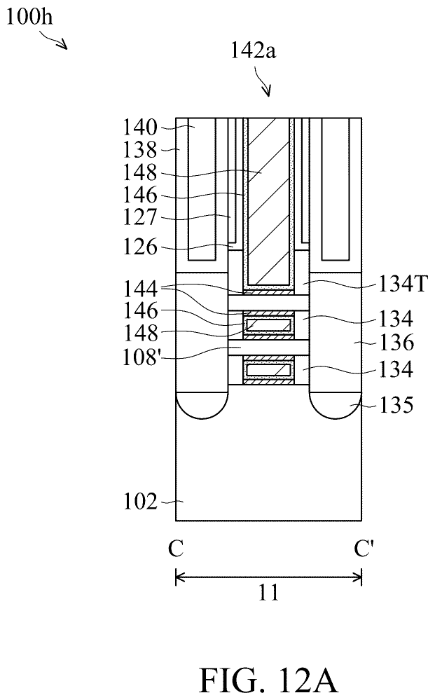

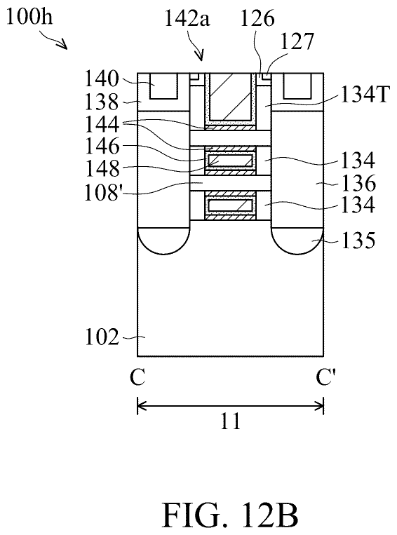

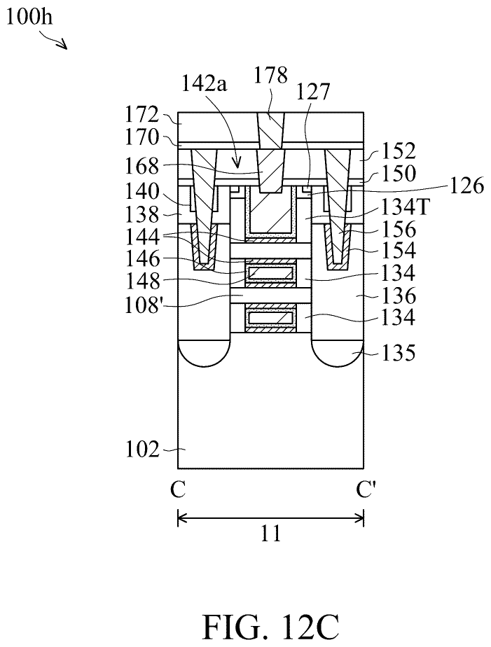

FIGS. 12A to 12C illustrate cross-sectional representations of various stages of manufacturing a semiconductor structure 100h, in accordance with some embodiments. The semiconductor structure 100h of FIGS. 12A-12C includes elements that are similar to, or the same as, elements of the semiconductor structure 100a of FIGS. 3A-3 to 3K-3.

The semiconductor structure 100h of FIG. 12A is similar to the semiconductor structure 100a of FIG. 3J-3, the difference between the FIG. 12 and FIG. 3J-3 is that a second gate spacer 127 is formed on the gate spacer layer 126. The second gate spacer layer 127 and the gate spacer layer 126 are made of different materials, and the interface is between the second gate spacer layer 127 and the gate spacer layer 126. In some other embodiments, a third gate spacer layer (not shown) is formed on the second gate spacer layer 127.

In addition, the gate spacer layer 126 has a L-shaped structure with a vertical portion and a horizontal portion. The outer sidewall surface of second gate spacer layer 127 is substantially aligned with the outer sidewall surface of gate spacer layer 126. In addition, the bottom surface of the gate spacer layer 126 is lower than the bottom surface of the second gate spacer layer 127. The CESL 138 is in contact with the second gate spacer layer 127 and the gate spacer layer 126. The second gate spacer layer 127 is separated from the topmost inner spacer layer 134T by the gate spacer layer 126.

In some embodiments, the second gate spacer layers 127 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), applicable low-k dielectric materials, and/or a combination thereof. The second gate spacer layers 127 may be formed by chemical vapor deposition (CVD), physical vapor deposition, (PVD), atomic layer deposition (ALD), or other applicable processes.

Next, as shown in FIG. 12B, the top portions of the first gate structure 142a and the second gate structure 142b are removed, and a top portion of the gate spacer layers 126 and a top portion of second gate spacer layer 127 directly on the nanostructures 108′ are removed, in accordance with some embodiments.

After the removal process, a portion of the gate spacer layer 126 and the second gate spacer layer 127 is remaining. Therefore, the top surface of the first gate structure 142a and the second gate structure 142b are substantially coplanar with the top surface of the top surface of the gate spacer layer 126 and the top surface of the second gate spacer layer 127. The remaining the gate spacer layer 126 still have L-shaped structure. The height of the second gate spacer layer 127 is smaller than the height of the gate spacer layer 126 in a vertical direction.

In some embodiments, the top portions of the first gate structure 142a, the top portions of the second gate structure 142b, the top portion of the gate spacer layers 126 and the top portion of the second gate spacer layer 127 are removed by a polishing process, such as CMP (Chemical-Mechanical Planarization) process.

Afterwards, as shown in FIG. 12C, the etch stop layer 150 is formed over the gate structure 142, and the dielectric layer 152 is formed over the etch stop layer 150, in accordance with some embodiments. Next, the silicide layer 154 and the S/D contact structure 156 are formed over the S/D structure 136, in accordance with some embodiments. The S/D contact structure 156 is electrically connected to the S/D structure 136. The gate conductive plug 168 is formed over the first gate structure 142a and the second gate structure 142b

Next, an etch stop layer 170 is formed on the dielectric layer 152, and a dielectric layer 172 is formed on the etch stop layer 170. A gate conductive via 178 is formed through the etch stop layer 170 and the dielectric layer 152. In addition, the gate conductive via 178 is formed on and electrically connected to the gate conductive plug 168.

The bottom surface of the S/D contact structure 156 is lower than the top surface of the topmost inner spacer layer 134T. In addition, the CESL 138 is in contact with the topmost inner spacer layer 134T. More specifically, the bottom surface of the CESL 138 is lower than the top surface of the topmost inner spacer layer 134T. The topmost inner spacer layer 134T is in contact with the interface between the CESL 138 and the S/D structure 136.

In addition, the etch stop layer 150 is formed on the first gate structure 142a, and the gate spacer layer 126 and the second gate spacer layer 127, and the etch stop layer 150 is in contact with the gate spacer layer 126 and the second gate spacer layer 127.

In some embodiments, the etch stop layer 170 and the etch stop layer 150 are made of the same material. In some embodiments, the etch stop layer 170 is made of a dielectric materials, such as silicon nitride, silicon oxide, silicon oxynitride, another suitable dielectric material, or a combination thereof. The dielectric material for the etch stop layer 170 may be conformally deposited over the semiconductor structure by performing chemical vapor deposition (CVD), ALD, other application methods, or a combination thereof.

In some embodiments, the dielectric layer 172 and the dielectric layer 152 are made of the same material. The dielectric layer 172 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 172 may be formed by chemical vapor deposition (CVD), physical vapor deposition, (PVD), atomic layer deposition (ALD), or other applicable processes.

In some embodiments, the gate conductive via 178 is made of conductive material, such as tungsten (W), ruthenium (Ru), molybdenum (Mo), or the like. In some embodiments, the gate conductive via 178 is formed by performing a deposition process, such as chemical vapor deposition (CVD), physical vapor deposition, (PVD), atomic layer deposition (ALD), or other applicable processes.

The uniformity of the profiles of the gate structure (142a/142b) are improved, and the variation of threshold voltage (Vt) of the semiconductor structure 100a and the variation of the DIBL (Drain Induced Barrier Lowering) are improved. Therefore, the performance of the semiconductor structure 100h is improved.

It should be appreciated that the semiconductor structures 100a to 100h having the top surface of the gate structure coplanar with the top surface of the topmost inner spacer layer described above may also be applied to FinFET structures, although not shown in the figures.

It should be noted that same elements in FIGS. 1A to 12C may be designated by the same numerals and may include similar or the same materials and may be formed by similar or the same processes; therefore such redundant details are omitted in the interest of brevity. In addition, although FIGS. 1A to 12C are described in relation to the method, it will be appreciated that the structures disclosed in FIGS. 1A to 12C are not limited to the method but may stand alone as structures independent of the method. Similarly, although the methods shown in FIGS. 1A to 12C are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a fin structure formed on a substrate. The fin structure includes first semiconductor material layers and the second semiconductor material layers alternatively stacked. A dummy gate structure is formed on the sidewall surfaces of the fin structure. A pair of gate spacer layers are formed on the sidewall surfaces of the gate structure. Next, an S/D structure is formed adjacent to the gate structure, and a plurality of inner spacer layers formed between the gate structure and the S/D structure. Next, the dummy gate structure is replaced with a gate structure. Afterwards, the top portion of the gate structure and the gate spacer layers are removed to expose the inner spacer layer. As a result, the profile of the gate structure is improved. In other words, the profile of the topmost gate structure is substantially the same with the profile of the bottommost gate structure. The unwanted footing issue of the gate structure is prevented. When the uniformity of the profiles of the gate structure are improved, the variation of threshold voltage (Vt) of the semiconductor structure and the variation of the DIBL (Drain Induced Barrier Lowering) are improved. Therefore, the performance of the semiconductor structure is improved.

In some embodiments, a semiconductor structure is provided. The semiconductor structure includes a plurality of first nanostructures formed over a substrate along a first direction, and a gate structure formed over the first nanostructures along a second direction. The semiconductor structure includes an S/D structure formed adjacent to the gate structure, and a dielectric layer formed on the S/D structure. The semiconductor structure includes a plurality of inner spacer layers between the gate structure and the S/D structure. A thickness of a topmost inner spacer layer is greater than a thickness of a bottommost inner spacer layer, and a top surface of the topmost inner spacer layer is higher than a bottom surface of the dielectric layer.

In some embodiments, a semiconductor structure is provided. The semiconductor structure includes a plurality of first nanostructures formed over a substrate, and an S/D structure formed adjacent to the first nanostructure. The semiconductor structure includes an inner spacer layer formed on a topmost first nanostructure, and a first etch stop layer formed on the S/D structure. A topmost surface of the inner spacer layer is higher than a bottom surface of the first etch stop layer.

In some embodiments, a method for forming a semiconductor structure is provided. The method includes forming a first fin structure over a substrate and the first fin structure includes first semiconductor material layers and second semiconductor material layers alternately stacked. The method includes forming a dummy gate structure over the first fin structure, and forming a gate spacer layer adjacent to the dummy gate structure. The method includes replacing the first semiconductor material layers with dielectric layers, and removing a portion of the dielectric layers to form notches. The method includes forming a plurality of inner spacer layers in the notches, and the gate spacer layer is on the inner spacer layers, and the dielectric constant of the gate spacer layer is lower than the dielectric constant of the inner spacer layer. The method includes removing the dummy gate structure, and removing the dielectric layers to expose the second semiconductor material layers and to form a trench. The method includes forming a gate structure in the trench, and removing a top portion of the gate structure and a top portion of the gate spacer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of first nanostructures formed over a substrate along a first direction;
a gate structure formed over the first nanostructures along a second direction;
an S/D structure formed adjacent to the gate structure;
a dielectric layer formed on the S/D structure; and
a plurality of inner spacer layers between the gate structure and the S/D structure, wherein a thickness of a topmost inner spacer layer is greater than a thickness of a bottommost inner spacer layer, and a top surface of the topmost inner spacer layer is higher than a bottom surface of the dielectric layer.

2. The semiconductor structure as claimed in claim 1, wherein the top surface of the topmost inner spacer layer is higher than a top surface of a topmost first nanostructure.

3. The semiconductor structure as claimed in claim 1, wherein a top surface of the gate structure is substantially coplanar with the top surface of the topmost inner spacer layer.

4. The semiconductor structure as claimed in claim 1, further comprising:
a gate spacer layer over the topmost inner spacer layer, wherein a height of the gate spacer layer is less than a height of the topmost inner spacer layer.

5. The semiconductor structure as claimed in claim 1, further comprising:
an etch stop layer formed on the S/D structure, wherein the etch stop layer is in contact with the topmost inner spacer layer.

6. The semiconductor structure as claimed in claim 1, further comprising:
an S/D contact structure formed on the S/D structure, wherein a bottom surface of the S/D contact structure is lower than the top surface of the topmost inner spacer layer.

7. The semiconductor structure as claimed in claim 1, further comprising:
a plurality of second nanostructures adjacent to the first nanostructures; and
an dielectric wall between the first nanostructures and the second nanostructures.

8. The semiconductor structure as claimed in claim 7, wherein a top surface of the dielectric wall is lower than a top surface of the S/D structure.

9. The semiconductor structure as claimed in claim 1, further comprising:
a plurality of second nanostructures over the first nanostructures, wherein a topmost surface of the inner spacer layers is higher than a top surface of a topmost second nanostructure.

10. A semiconductor structure, comprising:
a plurality of first nanostructures formed over a substrate;
an S/D structure formed adjacent to the first nanostructure;
an inner spacer layer formed on a topmost first nanostructure; and
a first etch stop layer formed on the S/D structure, wherein a topmost surface of the inner spacer layer is higher than a bottom surface of the first etch stop layer.

11. The semiconductor structure as claimed in claim 10, further comprising:
a gate spacer layer over the inner spacer layer, wherein a height of the gate spacer layer is less than a height of the inner spacer layer.

12. The semiconductor structure as claimed in claim 10, further comprising:
an isolation structure over the substrate; and
a gate spacer layer formed on the isolation structure, wherein the gate spacer layer and the inner spacer layer are made of different materials.

13. The semiconductor structure as claimed in claim 10, further comprising:
a second etch stop layer on the inner spacer layer and the S/D structure, wherein the second etch stop layer is in contact with the inner spacer layer.

14. The semiconductor structure as claimed in claim 10, wherein the inner spacer layer is in contact with an interface between the first etch stop layer and the S/D structure.

15. The semiconductor structure as claimed in claim 10, further comprising:
a plurality of second nanostructures adjacent to the first nanostructures; and
an isolation dielectric structure between the first nanostructures and the second nanostructures.

16. The semiconductor structure as claimed in claim 10, further comprising:
a plurality of second nanostructures over the first nanostructures, wherein the topmost surface of the inner spacer layer is higher than a top surface of a topmost second nanostructure; and
a middle dielectric layer between the first nanostructures and the second nanostructures.

17. A method for forming a semiconductor structure, comprising:
forming a first fin structure over a substrate, wherein the first fin structure comprises first semiconductor material layers and second semiconductor material layers alternately stacked;
forming a dummy gate structure over the first fin structure;
forming a gate spacer layer adjacent to the dummy gate structure;
replacing the first semiconductor material layers with dielectric layers;
removing a portion of the dielectric layers to form notches ;
forming a plurality of inner spacer layers in the notches, wherein the gate spacer layer is on the inner spacer layers, and a dielectric constant of the gate spacer layer is lower than a dielectric constant of the inner spacer layer;
removing the dummy gate structure;
removing the dielectric layers to expose the second semiconductor material layers and to form a trench;
forming a gate structure in the trench; and
removing a top portion of the gate structure and a top portion of the gate spacer layer.

18. The method for forming the semiconductor structure as claimed in claim 17, further comprising:
removing a portion of the first fin structure to form an S/D recess; and
after forming the S/D recess, replacing the first semiconductor material layers with dielectric layers.

19. The method for forming the semiconductor structure as claimed in claim 18, further comprising:
forming an S/D structure in the S/D recess, wherein a top surface of a topmost inner spacer layer is higher than a top surface of the S/D structure.

20. The method for forming the semiconductor structure as claimed in claim 17, further comprising:
forming a second fin structure adjacent to the first fin structure; and
forming an isolation dielectric structure between the first fin structure and the second fin structure.
